(19) United States
(12) Patent Application Publication
(10) Pub. No.: US 2025/0351556 A1
(43) Pub. Date: Nov. 13, 2025

(54) SEMICONDUCTOR DEVICE

(71) Applicant: Nuvoton Technology Corporation Japan, Kyoto (JP)

(72) Inventors: Eiji YASUDA, Kyoto (JP); Tadashi SASAKI, Kyoto (JP); Kouki YAMAMOTO, Kyoto (JP); Yusuke ITO, Kyoto (JP); Akira KIMURA, Kyoto (JP)

(21) Appl. No.: 19/278,470

(22) Filed: Jul. 23, 2025

Related U.S. Application Data
(63) Continuation of application No. PCT/JP2024/017779, filed on May 14, 2024.
(60) Provisional application No. 63/510,507, filed on Jun. 27, 2023.
(60) Provisional application No. 63/515,265, filed on Jul. 24, 2023.

(51) Int. Cl. H10D 84/80; H10D 1/47; H10D 8/00; H10D 8/25; H10D 30/63; H10D 62/10; H10D 62/60; H10D 64/27; H10D 89/60

(52) U.S. Cl. CPC H10D 84/811; H10D 1/47; H10D 8/25; H10D 8/411; H10D 30/63; H10D 62/106; H10D 62/126; H10D 62/60; H10D 64/513; H10D 89/611; H10D 89/911

(57) ABSTRACT

A semiconductor device includes: a semiconductor layer divided into a first region, a second region, and a third region that do not overlap each other in a plan view; a first vertical metal-oxide-semiconductor (MOS) transistor provided in the first region; a second vertical MOS transistor provided in the second region; and a third vertical MOS transistor provided in the third region. First gate wiring of the first vertical MOS transistor and third gate wiring of the third vertical MOS transistor are electrically connected in series via a first diode, with stated order being a forward direction. Second gate wiring of the second vertical MOS transistor and the third gate wiring are electrically connected in series via a second diode, with stated order being a forward direction.

### CROSS REFERENCE TO RELATED APPLICATIONS

This is a continuation application of PCT International Patent Application No. PCT/JP2024/017779 filed on May 14, 2024, designating the United States of America, which is based on and claims priority of U.S. Provisional Patent Application No. 63/510,507 filed on Jun. 27, 2023 and U.S. Provisional Patent Application No. 63/515,265 filed on Jul. 24, 2023. The entire disclosures of the above-identified applications, including the specifications, drawings and claims are incorporated herein by reference in their entirety.

### FIELD

The present disclosure relates to semiconductor devices and, more specifically, to chip-size-package type semiconductor devices.

### BACKGROUND

At least one vertical MOS transistor can be used in an electrical circuit that integrates two paths that differ in current value in specification into one path.

### CITATION LIST

### Patent Literature

PTL 1: Japanese Patent No. 7253674

### SUMMARY

### Technical Problem

There has been a demand for downsizing a circuit including at least one vertical MOS transistor.

### Solution to Problem

In order to solve the above problem, a semiconductor device according to one aspect of the present disclosure is a facedown mountable, chip-size-package type semiconductor device, the semiconductor device comprising: a semiconductor layer that includes a semiconductor substrate on a back face side and is divided into a first region, a second region, and a third region that do not overlap each other and are not dispersedly disposed in a plan view of the semiconductor device; a first vertical metal-oxide-semiconductor (MOS) transistor an entirety of which is provided in the first region of the semiconductor layer; a second vertical MOS transistor an entirety of which is provided in the second region of the semiconductor layer; a third vertical MOS transistor an entirety of which is provided in the third region of the semiconductor layer; and a metal layer that is provided in contact with the back face side of the semiconductor layer, wherein the semiconductor substrate is a common drain region of the first vertical MOS transistor, the second vertical MOS transistor, and the third vertical MOS transistor, in the plan view, a first source pad and a first gate pad of the first vertical MOS transistor and first gate wiring connected to the first gate pad are provided at positions within the first region, in the plan view, a second source pad and a second gate pad of the second vertical MOS transistor and second gate wiring connected to the second gate pad are provided at positions within the second region, in the plan view, a third source pad of the third vertical MOS transistor and third gate wiring are provided at positions within the third region, the first gate wiring and the third gate wiring are electrically connected in series via a first diode in a direction from the first gate wiring to the third gate wiring as a forward direction, and the second gate wiring and the third gate wiring are electrically connected in series via a second diode in a direction from the second gate wiring to the third gate wiring as a forward direction.

### Advantageous Effects

It is possible to decrease an area required by a circuit that integrates, for example, two conductive paths that differ in current value in specification into one conductive path more than ever before, by applying the semiconductor device including the above three vertical MOS transistors to the circuit.

Accordingly, the semiconductor device thus configured makes it possible to downsize the circuit including the at least one vertical MOS transistor.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional schematic diagram showing an example of the structure of a semiconductor device according to an embodiment.

FIG. 2A is a planar schematic diagram showing an example of the structure of the semiconductor device according to the embodiment.

FIG. 2B is a planar schematic diagram showing an example of the structure of the semiconductor device according to the embodiment.

FIG. 3A is a planar schematic diagram showing an example of a portion of the structure of the semiconductor device according to the embodiment.

FIG. 3B is a cross-sectional schematic diagram showing an example of the portion of the structure of the semiconductor device according to the embodiment.

FIG. 3C is a cross-sectional schematic diagram showing an example of a portion of the structure of the semiconductor device according to the embodiment.

FIG. 4A is a planar schematic diagram showing an example of a portion of the structure of the semiconductor device according to the embodiment.

FIG. 4B is a cross-sectional schematic diagram showing an example of the portion of the structure of the semiconductor device according to the embodiment.

FIG. 4C is a cross-sectional schematic diagram showing an example of a portion of the structure of the semiconductor device according to the embodiment.

FIG. 5A is a planar schematic diagram showing an approximate single unit configuration of a first transistor according to the embodiment.

FIG. 5B is a perspective schematic diagram showing the approximate single unit configuration of the first transistor according to the embodiment.

FIG. 6 is a circuit diagram showing an example of using the semiconductor device according to the embodiment.

FIG. 7 is a circuit diagram showing an example of using a semiconductor device according to a comparative example.

FIG. 8A is a planar schematic diagram showing an example of the structure of a transistor according to the comparative example.

FIG. 8B is a planar schematic diagram showing an example of the structure of the transistor according to the comparative example.

FIG. 9A is a planar schematic diagram showing an example of the structure of a transistor according to a comparative example.

FIG. 9B is a planar schematic diagram showing an example of the structure of the transistor according to the comparative example.

FIG. 10A is a planar schematic diagram showing a variation of the structure of a semiconductor device according to the embodiment.

FIG. 10B is a planar schematic diagram showing the variation of the structure of the semiconductor device according to the embodiment.

FIG. 11 is a graph that shows a relation between an area and an ESD tolerance in a plan view of a transistor.

### DESCRIPTION OF EMBODIMENT

The embodiment described below shows a specific example of the present disclosure. Numerical values, shapes, materials, constituent elements, the arrangement and connection of the constituent elements, etc. shown in the following embodiment are mere examples, and are not intended to limit the scope of the present disclosure.

In the present disclosure, the terminology “A and B are electrically connected” includes configurations in which A and B are directly connected via wiring, configurations in which A and B are directly connected not via wiring, and configurations in which A and B are indirectly connected via a resistance component (resistance element, resistance wiring).

### EMBODIMENT

### 1. Structure of Semiconductor Device

Hereinafter, the structure of a semiconductor device according to an embodiment is described. The semiconductor device according to the embodiment is a facedown mountable, chip-size-package (CSP) type semiconductor device that includes a triple configuration in which three vertical metal-oxide-semiconductor (MOS) transistors are provided in a semiconductor substrate. The above three vertical MOS transistors are power transistors and what is called trench MOS field-effect transistors (FETs).

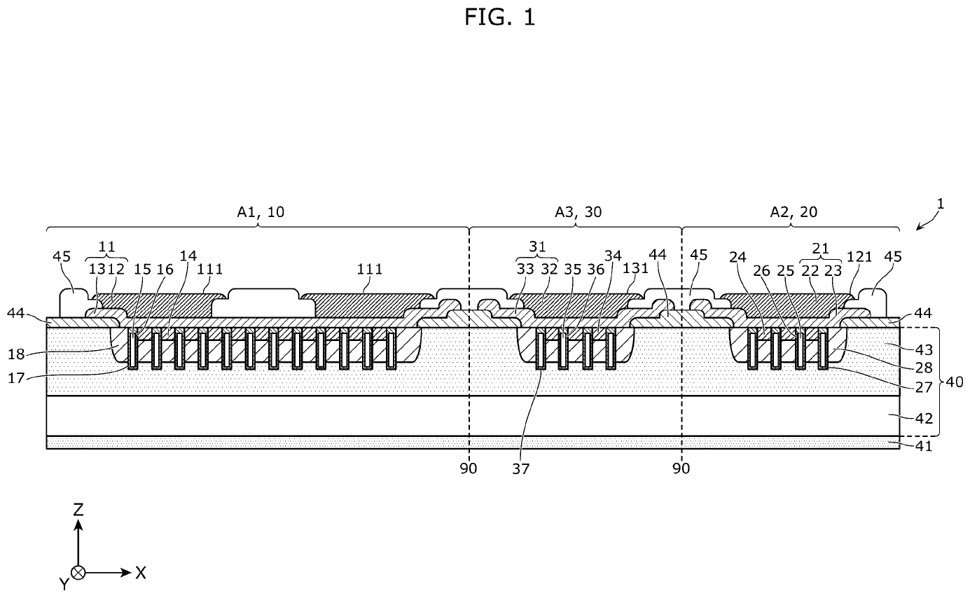

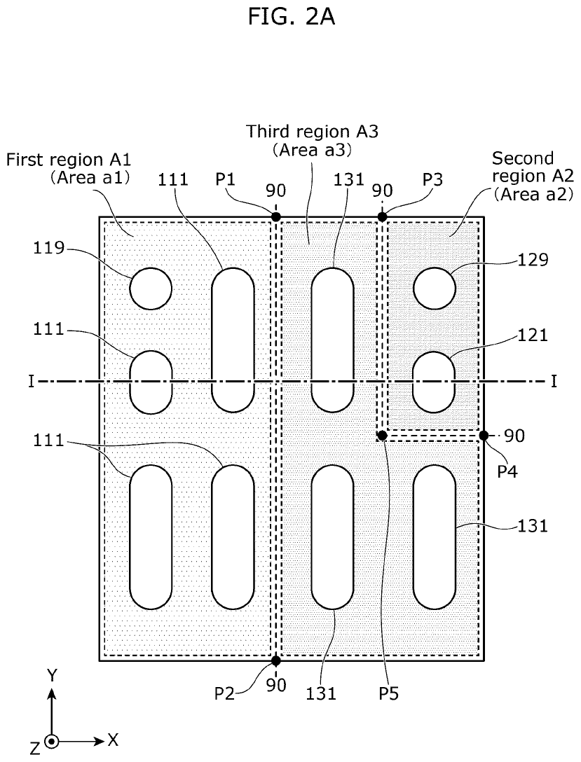

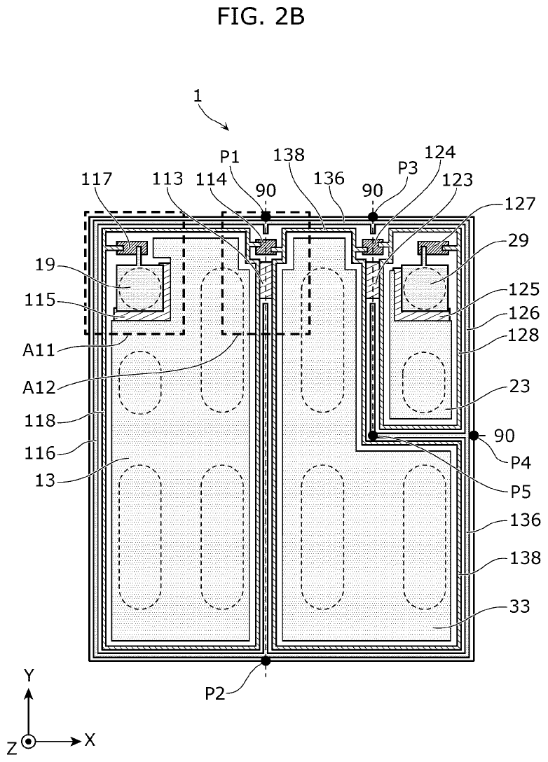

FIG. 1 is a cross-sectional schematic diagram showing an example of the structure of semiconductor device 1 according to the embodiment. FIG. 2A and FIG. 2B each are a planar schematic diagram showing an example of the structure of semiconductor device 1 according to the embodiment. The size and shape of semiconductor device 1 in FIG. 2A and FIG. 2B are an example. In addition, the size, shape, and arrangement of pads and electrodes are also an example.

It should be noted that FIG. 2B shows a state immediately after portion 13 of first source electrode 11, first gate electrode 19, first gate wiring 118, portion 23 of second source electrode 21, second gate electrode 29, second gate wiring 128, portion 33 of third source electrode 31, and third gate wiring 138 are provided on a front face side of semiconductor layer 40. Pads that cannot be seen at this moment are indicated by dashed lines. Each of the constituent elements is described later.

FIG. 1 shows a section when semiconductor device 1 is cut along line I-I in FIG. 2A.

As shown in FIG. 1, semiconductor device 1 includes semiconductor substrate 42, metal layer 41, low-concentration impurity layer 43 provided on semiconductor substrate 42. In the present disclosure, semiconductor substrate 42 and low-concentration impurity layer 43 are collectively referred to as semiconductor layer 40.

Semiconductor substrate 42 is disposed on a back face side of semiconductor layer 40 and includes silicon of a first conductivity type that contains impurities having a first concentration. Semiconductor layer 40 includes low-concentration impurity layer 43 of the first conductivity type that is provided in contact with semiconductor substrate 42 and includes impurities having a second concentration lower than the first concentration. Low-concentration impurity layer 43 is provided on semiconductor substrate 42 by, for example, epitaxial growth.

As shown in FIG. 1 and FIG. 2A, semiconductor device 1 includes: first vertical MOS transistor 10 (hereinafter also referred to as “transistor 10”) the entirety of which is provided in first region A1 of semiconductor layer 40; second vertical MOS transistor 20 (hereinafter also referred to as “transistor 20”) the entirety of which is provided in second region A2 of semiconductor layer 40; and third vertical MOS transistor 30 (hereinafter also referred to as “transistor 30”) the entirety of which is provided in third region A3 of semiconductor layer 40.

That the entirety of transistor 10 is provided in first region A1 means that, in a plan view, all elements included in transistor 10 are located within first region A1 and are not located in a region other than first region A1. Similarly, that the entirety of transistor 20 is provided in second region A2 means that, in the plan view, all elements included in transistor 20 are located within second region A2 and are not located in a region other than second region A2. Likewise, that the entirety of transistor 30 is provided in third region A3 means that, in the plan view, all elements included in transistor 30 are located within third region A3 and are not located in a region other than third region A3.

As shown in FIG. 2A, in the plan view, the front face side of semiconductor layer 40 is divided into first region A1, second region A2, and third region A3 that do not overlap each other and are not dispersedly disposed. Here, that first region A1, second region A2, and third region A3 are not dispersedly disposed means that each of first region A1, second region A2, and third region A3 does not have an enclave. In FIG. 2A, virtual boundary lines 90 that separate first region A1, second region A2, and third region A3 are indicated by dashed lines. Although the dashed lines indicating boundary lines 90 are extended to the outside of semiconductor layer 40 for the sake of clarity, actual boundary lines 90 end at the outer periphery of semiconductor layer 40 in the plan view. (In FIG. 2A and FIG. 2B, for descriptive purposes, the ends of boundary lines 90 are indicated by P1, P2, P3, and P4.) Boundary lines 90 are described later.

It should be noted that, in FIG. 2A, dashed lines indicating first region A1, second region A2, and third region A3 are not caused to strictly coincide with the outer periphery of semiconductor layer 40 and boundary lines 90 for the sake of clarity and are shown on the inside of the outer periphery of semiconductor layer 40 and boundary lines 90 with slight margins therebetween. However, the outer periphery of first region A1, the outer periphery of second region A2, and the outer periphery of third region A3 substantially coincide with the outer periphery of semiconductor layer 40 and boundary lines 90. In the plan view, semiconductor device 1 according to the embodiment does not include a region that is not first region A1, second region A2, or third region A3.

Metal layer 41 is provided in contact with the back face side of semiconductor layer 40 and may include, as a non-limiting example, silver (Ag) or copper (Cu). It should be noted that metal layer 41 may include a trace amount of a chemical element other than metal mixed in as impurities in a manufacturing process for a metal material.

As shown in FIG. 1, first body region 18 of a second conductivity type different from the first conductivity type is provided in first region A1 of low-concentration impurity layer 43. First source region 14 of the first conductivity type is provided in first body region 18.

Moreover, a plurality of first gate trenches 17 that penetrate through first source region 14 and first body region 18 from a top face of semiconductor layer 40 to a depth that reaches a portion of low-concentration impurity layer 43 are provided in first region A1. Furthermore, first gate conductor 15 is provided on first gate insulating film 16 inside each of the plurality of first gate trenches 17. First gate conductor 15 is an embedded gate electrode embedded inside semiconductor layer 40. First gate conductor 15 is electrically connected to first gate electrode 19 via first gate wiring 118 (see FIG. 2B).

First source electrode 11 includes portion I2 and portion 13. Portion 12 is connected to first source region 14 and first body region 18 via portion 13.

Portion 12 of first source electrode 11 is a layer joined with solder at the time of reflow in facedown mounting, and may include, as a non-limiting example, a metal material including at least one of nickel, titanium, tungsten, or palladium. The surface of portion 12 may be plated with, for example, gold.

Portion 13 of first source electrode 11 is a layer that connects portion 12 and semiconductor layer 40, and may include, as a non-limiting example, a metal material including at least one of aluminum, copper, gold, or silver.

First gate electrode 19 may be provided simultaneously with first source electrode 11, and may include at least one of the same configuration or the same material as first source electrode 11.

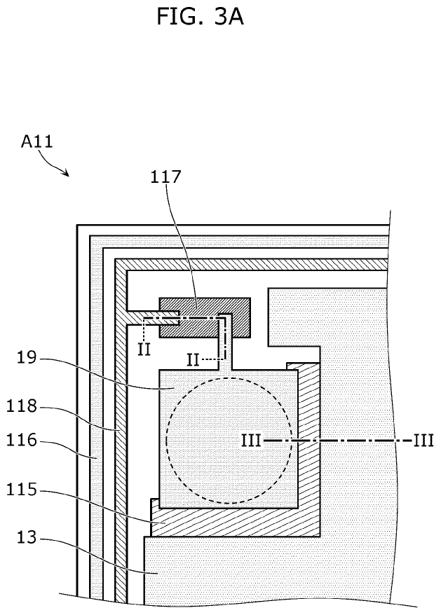

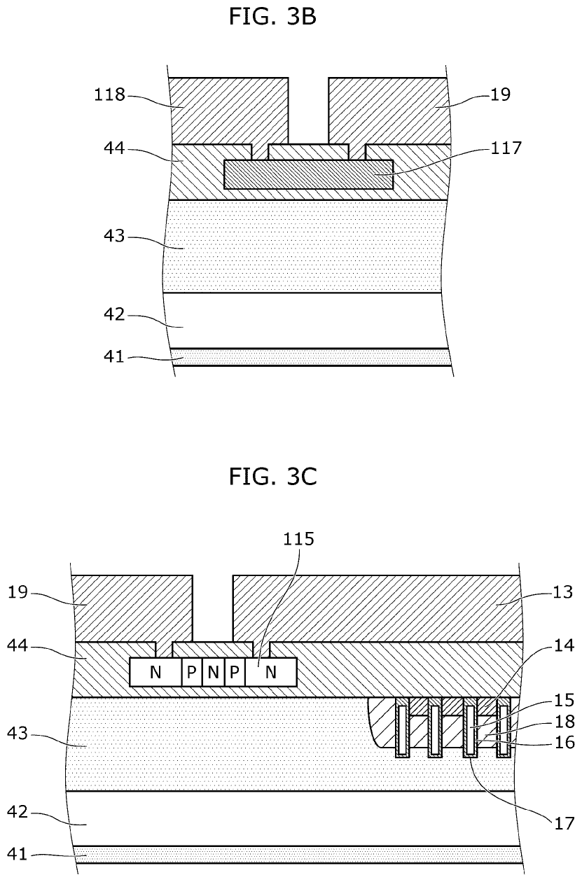

As shown in FIG. 2B, first gate wiring 118 is disposed to surround portion 13 of first source electrode 11 and first gate electrode 19 in the plan view. First gate wiring 118 is connected in series with first gate electrode 19 via first gate resistance element 117. FIG. 3B shows a cross-sectional schematic diagram including first gate resistance element 117. FIG. 3B is a section when semiconductor device 1 is cut along line II-II in FIG. 3A. FIG. 3A is a planar schematic diagram that shows enlarged region A11 surrounded by the dashed line in FIG. 2B.

As shown in FIG. 2B, first Zener diode 115 is disposed between portion 13 of first source electrode 11 and first gate electrode 19 in the plan view. FIG. 3C shows a cross-sectional schematic diagram including first Zener diode 115. FIG. 3C shows a section when semiconductor device 1 is cut along line III-III in FIG. 3A. First gate electrode 19 and portion 13 of first source electrode 11 are electrically connected via first Zener diode 115.

A gate resistance element and a Zener diode are both disposed in expectation of a protective function of protecting a transistor from destruction when an excessive voltage is applied to a gate electrode. In other words, the gate resistance element and the Zener diode are elements disposed to improve electrostatic discharge (ESD) tolerance. First gate resistance element 117 and first Zener diode 115 may both be formed by injecting impurities into, for example, polysilicon. By controlling types, injection amounts, and injection positions of impurities, it is possible to control a resistivity of first gate resistance element 117 or positions, the number, and electrical directions of PN junctions in first Zener diode 115.

For example, as shown in FIG. 3C, first Zener diode 115 may alternately include: a portion of the first conductivity type into which impurities of the first conductivity type are injected; and a portion of the second conductivity type into which impurities of the second conductivity type are injected. In the example shown in FIG. 3C, two PN junctions are provided between first gate electrode 19 and portion 13 of first source electrode 11 in both directions by first Zener diode 115.

First equipotential ring (EQR) 116 that is electrically connected to semiconductor substrate 42 may be disposed on the outer periphery of first region A1 in the plan view. First EQR 116 is disposed in transistor 10 in expectation of a function of stopping the flow of a leakage current between the outside and first body region 18. First EQR 116 may include, as a non-limiting example, a metal material including at least one of aluminum, copper, gold, or silver.

It should be noted that a gate resistance element, a Zener diode, and an EQR need not be disposed in semiconductor device 1 according to the embodiment.

Second body region 28 of the second conductivity type is provided in second region A2 of low-concentration impurity layer 43. Second source region 24 of the first conductivity type is provided in second body region 28.

Moreover, a plurality of second gate trenches 27 that penetrate through second source region 24 and second body region 28 from the top face of semiconductor layer 40 to a depth that reaches a portion of low-concentration impurity layer 43 are provided in second region A2. Furthermore, second gate conductor 25 is provided on second gate insulating film 26 inside each of the plurality of second gate trenches 27. Second gate conductor 25 is an embedded gate electrode embedded inside semiconductor layer 40. Second gate conductor 25 is electrically connected to second gate electrode 29 via second gate wiring 128 (see FIG. 2B).

Second source electrode 21 includes portion 22 and portion 23. Portion 22 is connected to second source region 24 and second body region 28 via portion 23.

Portion 22 of second source electrode 21 is a layer joined with solder at the time of reflow in facedown mounting, and may include, as a non-limiting example, a metal material including at least one of nickel, titanium, tungsten, or palladium. The surface of portion 22 may be plated with, for example, gold.

Portion 23 of second source electrode 21 is a layer that connects portion 22 and semiconductor layer 40, and may include, as a non-limiting example, a metal material including at least one of aluminum, copper, gold, or silver.

Second gate electrode 29 may be provided simultaneously with second source electrode 21, and may at least have the same configuration as second source electrode 21 or include the same material as second source electrode 21.

As shown in FIG. 2B, second gate wiring 128 is disposed to surround portion 23 of second source electrode 21 and second gate electrode 29 in the plan view. Second gate wiring 128 is connected in series with second gate electrode 29 via second gate resistance element 127.

As shown in FIG. 2B, second Zener diode 125 is disposed between portion 23 of second source electrode 21 and second gate electrode 29 in the plan view. Second gate electrode 29 and portion 23 of second source electrode 21 are electrically connected via second Zener diode 125.

Second gate resistance element 127 and second Zener diode 125 may both be formed by injecting impurities into, for example, polysilicon. By controlling types, injection amounts, and injection positions of impurities, it is possible to control a resistivity of second gate resistance element 127 or positions, the number, and electrical directions of PN junctions in second Zener diode 125.

Second Zener diode 125 may have the same structure as first Zener diode 115 shown in, for example, FIG. 3C.

Second EQR 126 that is electrically connected to semiconductor substrate 42 may be disposed on the outer periphery of second region A2 in the plan view. Second EQR 126 is disposed in transistor 20 in expectation of a function of stopping the flow of a leakage current between the outside and second body region 28. Second EQR 126 may include, as a non-limiting example, a metal material including at least one of aluminum, copper, gold, or silver.

Third body region 38 of the second conductivity type is provided in third region A3 of low-concentration impurity layer 43. Third source region 34 of the first conductivity type is provided in third body region 38. Moreover, a plurality of third gate trenches 37 that penetrate through third source region 34 and third body region 38 from the top face of semiconductor layer 40 to a depth that reaches a portion of low-concentration impurity layer 43 are provided in third region A3. Furthermore, third gate conductor 35 is provided on third gate insulating film 36 inside each of the plurality of third gate trenches 37. Third gate conductor 35 is an embedded gate electrode embedded inside semiconductor layer 40. Third gate conductor 35 is electrically connected to third gate wiring 138 (see FIG. 2B).

Third source electrode 31 includes portion 32 and portion 33. Portion 32 is connected to third source region 34 and third body region 38 via portion 33.

Portion 32 of third source electrode 31 is a layer joined with solder at the time of reflow in facedown mounting, and may include, as a non-limiting example, a metal material including at least one of nickel, titanium, tungsten, or palladium. The surface of portion 32 may be plated with, for example, gold.

Portion 33 of third source electrode 31 is a layer that connects portion 32 and semiconductor layer 40, and may include, as a non-limiting example, a metal material including at least one of aluminum, copper, gold, or silver.

Third EQR 136 that is electrically connected to semiconductor substrate 42 may be disposed on the outer periphery of third region A3 in the plan view. Third EQR 136 is disposed in transistor 30 in expectation of a function of stopping the flow of a leakage current between the outside and third body region 38. Third EQR 136 may include, as a non-limiting example, a metal material including at least one of aluminum, copper, gold, or silver.

Although third gate wiring 138 is disposed to surround portion 33 of third source electrode 31 in the plan view as shown in FIG. 2B, a gate electrode connected to third gate wiring 138 and a gate pad are not present at positions within third region A3 in the present disclosure. It should be noted that a gate resistance element and a Zener diode that can be disposed in first region A1 or second region A2 are also not provided.

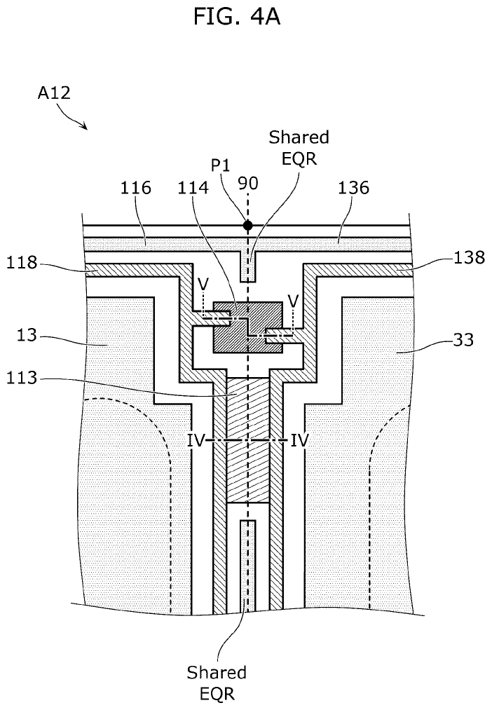

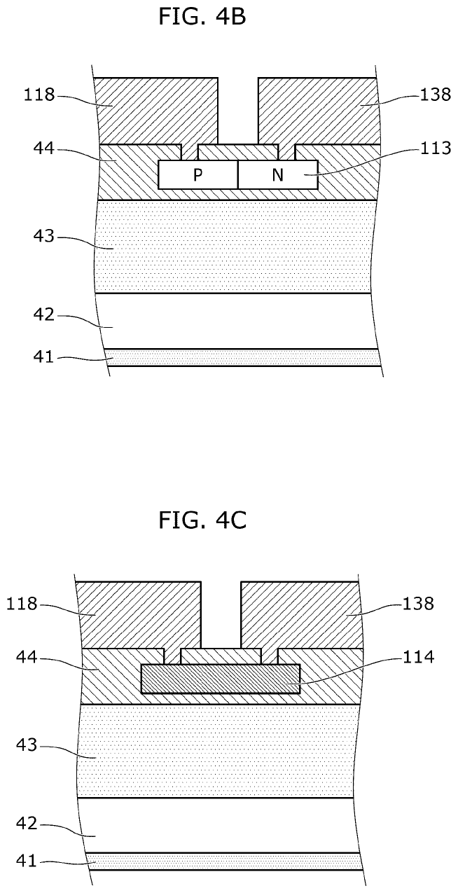

Third gate wiring 138 is connected in series with first gate wiring 118 via first diode 113. First diode 113 is provided in a direction from first gate wiring 118 to third gate wiring 138 as an electrically forward direction. FIG. 4B shows a cross-sectional schematic diagram including first diode 113. FIG. 4B is a section when semiconductor device 1 is cut along line IV-IV in FIG. 4A. FIG. 4A is a planar schematic diagram that shows enlarged region A12 surrounded by the dashed line in FIG. 2B.

Third gate wiring 138 is connected in series with first gate wiring 118 via first resistance element 114. Accordingly, first diode 113 and first resistance element 114 are connected in parallel between first gate wiring 118 and third gate wiring 138. FIG. 4C shows a cross-sectional schematic diagram including first resistance element 114. FIG. 4C shows a section when semiconductor device 1 is cut along line V-V in FIG. 4A.

First resistance element 114 and first diode 113 may both be formed by injecting impurities into, for example, polysilicon. By controlling types, injection amounts, and injection positions of impurities, it is possible to control a resistivity of first resistance element 114 or positions, the number, and electrical directions of PN junctions in first diode 113.

For example, as shown in FIG. 4B, first diode 113 may include: only one portion of the first conductivity type into which impurities of the first conductivity type are injected; and only one portion of the second conductivity type into which impurities of the second conductivity type are injected. In the example shown in FIG. 4B, only one PN junction is provided in the direction from first gate wiring 118 to third gate wiring 138 as the electrically forward direction.

Third gate wiring 138 is connected in series with second gate wiring 128 via second diode 123. Second diode 123 is provided in a direction from second gate wiring 128 to third gate wiring 138 as an electrically forward direction. In addition, third gate wiring 138 is connected in series with second gate wiring 128 via second resistance element 124. Accordingly, second diode 123 and second resistance element 124 are connected in parallel between second gate wiring 128 and third gate wiring 138.

Second resistance element 124 and second diode 123 may both be formed by injecting impurities into, for example, polysilicon. By controlling types, injection amounts, and injection positions of impurities, it is possible to control a resistivity of second resistance element 124 or positions, the number, and electrical directions of PN junctions in second diode 123.

Second diode 123 has the same structure as first diode 113 shown in, for example, FIG. 4B, and includes only one PN junction in the direction from second gate wiring 128 to third gate wiring 138 as the forward direction electrically.

As shown in FIG. 1, first body region 18 and first source region 14 are covered with interlayer insulating layer 44 including openings, and portion 13 of first source electrode 11 is connected to first source region 14 via the openings of interlayer insulating layer 44. Interlayer insulating layer 44 and portion 13 of first source electrode 11 are covered with passivation layer 45 including openings, and portion 12 is connected to portion 13 of first source electrode 11 via the openings of passivation layer 45.

Similarly, second body region 28 and second source region 24 are covered with interlayer insulating layer 44 including openings, and portion 23 of second source electrode 21 is connected to second source region 24 via the openings of interlayer insulating layer 44. Interlayer insulating layer 44 and portion 23 of second source electrode 21 are covered with passivation layer 45 including openings, and portion 22 is connected to portion 23 of second source electrode 21 via the openings of passivation layer 45.

Likewise, third body region 38 and third source region 34 are covered with interlayer insulating layer 44 including openings, and portion 33 of third source electrode 31 is connected to third source region 34 via the openings of interlayer insulating layer 44. Interlayer insulating layer 44 and portion 33 of third source electrode 31 are covered with passivation layer 45 including openings, and portion 32 is connected to portion 33 of third source electrode 31 via the openings of passivation layer 45.

Accordingly, as is also clear from FIG. 2B, first source pad 111, second source pad 121, and third source pad 131 refer to a region in which first source electrode 11 is partially exposed to the surface of semiconductor device 1, a region in which second source electrode 21 is partially exposed to the surface of semiconductor device 1, and a region in which third source electrode 31 is partially exposed to the surface of semiconductor device 1, respectively, that is, terminal portions. Similarly, first gate pad 119 and second gate pad 129 refer to a region in which first gate electrode 19 is partially exposed to the surface of semiconductor device 1 and a region in which second gate electrode 29 is partially exposed to the surface of semiconductor device 1, respectively, that is, terminal portions.

The number of first source pads 111, the number of second source pads 121, and the number of third source pads 131 are not necessarily limited to the respective numbers exemplified in FIG. 2A. Moreover, the shapes of first source pad 111, second source pad 121, and third source pad 131 are not necessarily limited to the respective obround shapes exemplified in FIG. 2A, and may be, for example, rectangular shapes or circular shapes. Furthermore, the positions of first source pad 111, second source pad 121, and third source pad 131 are not limited to the respective positions exemplified in FIG. 2A.

The number of first gate pads 119 and the number of second gate pads 129 are not necessarily limited to the respective numbers exemplified in FIG. 2A, and may be at least two. Moreover, the shapes of first gate pad 119 and second gate pad 129 are not limited to the respective circular shapes exemplified in FIG. 2A, and may be, for example, rectangular shapes or obround shapes.

The above-described configurations of transistor 10, transistor 20, and transistor 30 allow semiconductor substrate 42 and an area of low-concentration impurity layer 43 in the proximity of an area immediately above semiconductor substrate 42 to be a common drain region having a first drain region of transistor 10, a second drain region of transistor 20, and a third drain region of transistor 30 in common.

Metal layer 41 is a common drain electrode having a first drain electrode of transistor 10, a second drain electrode of transistor 20, and a third drain electrode of transistor 30 in common.

It should be noted that the center of a shape in the plan view is defined as follows in the present disclosure. The center of a circular shape such as first gate pad 119 in FIG. 2A refers to the center thereof. The center of a rectangular shape such as first region A1 refers to the intersection point of the diagonals thereof. The center of an obround shape such as first source pad 111 refers to the intersection point of a line-symmetric axis extending in a longitudinal direction of the obround shape and a line-symmetric axis extending in a width direction of the obround shape.

As shown in FIG. 2A, first region A1 and second region A2 are disposed on either side of third region A3. In the present disclosure, that first region A1 and second region A2 are on either side of third region A3 means that first region A1 and third region A3 are adjacent to each other without an other region therebetween, and second region A2 and third region A3 are adjacent to each other without an other region therebetween. Accordingly, third region A3 is adjacent to both first region A1 and second region A2 in a plan view of semiconductor layer 40.

That a region and another region are adjacent to each other in a plan view is similar in the sense that the region and the other region are opposite to each other, and means that the outer peripheries of the region and the other region coincide on boundary line 90 located therebetween. Hereinafter, the length of boundary line 90 may be referred to as an opposite length.

As shown in FIG. 2B, boundary line 90 between first region A1 and third region A3 may be viewed as a virtual line tracing the central position of a space between portion 13 of first source electrode 11 and portion 33 of third source electrode 31. Moreover, boundary line 90 may be viewed as the space itself having a limited width. Even when boundary line 90 is the space, the space can be recognized as a line by appearance to the naked eye or with low magnification. Boundary line 90 between first region A1 and third region A3 is the dashed line from P1 to P2 in the examples shown in FIG. 2A and FIG. 2B.

When first EQR 116 is disposed on the outer periphery of first region A1 and third EQR 136 is disposed on the outer periphery of third region A3 in the plan view, first EQR 116 and third EQR 136 may be shared as one EQR in a portion in which the outer periphery of first region A1 and the outer periphery of third region A3 coincide. The portion in which the shared EQR is disposed may be viewed as boundary line 90 between first region A1 and third region A3 in the plan view.

As shown in FIG. 2B, in semiconductor device 1 according to the embodiment, first diode 113 extends across boundary line 90 between first region A1 and third region A3 in the plan view. In other words, one end of first diode 113 is located in first region A1, and an other end of first diode 113 is located in third region A3.

As shown in FIG. 2B, in semiconductor device 1 according to the embodiment, first resistance element 114 extends across boundary line 90 between first region A1 and third region A3 in the plan view. To put it another way, one end of first resistance element 114 is located in first region A1, and an other end of first resistance element 114 is located in third region A3.

Boundary line 90 between second region A2 and third region A3 may be viewed as a virtual line tracing the central position of a space between portion 23 of second source electrode 21 and portion 33 of third source electrode 31. Moreover, boundary line 90 may be viewed as the space itself having a limited width. Boundary line 90 between second region A2 and third region A3 is the dashed line from P3 through P5 to P4 in the examples shown in FIG. 2A and FIG. 2B.

When second EQR 126 is disposed on the outer periphery of second region A2 and third EQR 136 is disposed on the outer periphery of third region A3 in the plan view, second EQR 126 and third EQR 136 may be shared as one EQR in a portion in which the outer periphery of second region A2 and the outer periphery of third region A3 coincide. The portion in which the shared EQR is disposed may be viewed as boundary line 90 between second region A2 and third region A3 in the plan view.

As shown in FIG. 2B, in semiconductor device 1 according to the embodiment, second diode 123 extends across boundary line 90 between second region A2 and third region A3 in the plan view. In other words, one end of second diode 123 is located in second region A2, and an other end of second diode 123 is located in third region A3.

As shown in FIG. 2B, in semiconductor device 1 according to the embodiment, second resistance element 124 extends across boundary line 90 between second region A2 and third region A3 in the plan view. To put it another way, one end of second resistance element 124 is located in second region A2, and an other end of second resistance element 124 is located in third region A3.

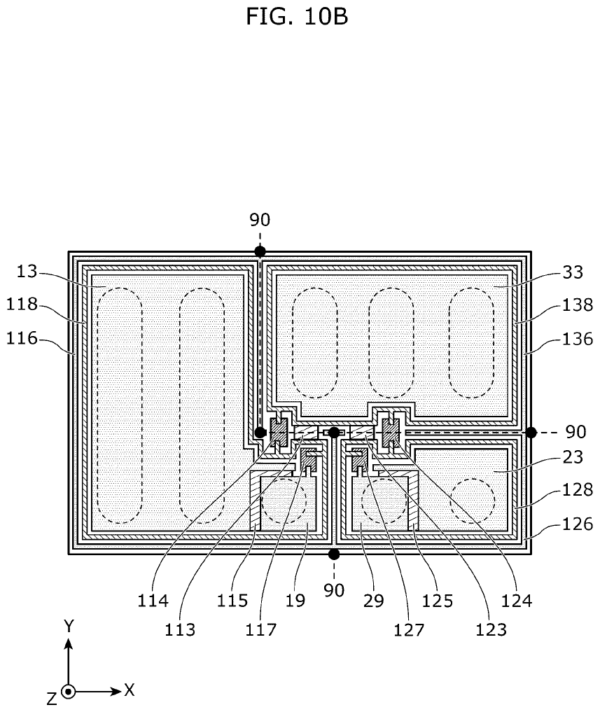

Although not shown in FIG. 2A and FIG. 2B, it is conceivable that first region A1 and second region A2 are adjacent to each other (see a variation shown in FIG. 10A and FIG. 10B). A boundary line between first region A1 and second region A2 may be viewed as a virtual line tracing the central position of a space between portion 13 of first source electrode 11 and portion 23 of second source electrode 21. Moreover, the boundary line may be viewed as the space itself having a limited width.

When first EQR 116 is disposed on the outer periphery of first region A1 and second EQR 126 is disposed on the outer periphery of second region A2 in the plan view, first EQR 116 and second EQR 126 may be shared as one EQR in a portion in which the outer periphery of first region A1 and the outer periphery of second region A2 coincide. The portion in which the shared EQR is disposed may be viewed as the boundary line between first region A1 and second region A2 in the plan view.

As shown in FIG. 2A and FIG. 2B, in semiconductor device 1 according to the embodiment, area a1 of first region A1 in the plan view is larger than area a3 of third region A3 in the plan view (a1>a3). Additionally, area a3 of third region A3 in the plan view is larger than area a2 of second region A2 in the plan view (a3>a2). Accordingly, first region A1, second region A2, and third region A3 satisfy a1>a3>a2 in terms of area in the plan view.

On the other hand, in the example shown in FIG. 2B, the area of portion 13 of first source electrode 11 provided in first region A1 in the plan view is substantially equal to the area of portion 33 of third source electrode 31 provided in third region A3 in the plan view. As described above, area a1 of first region A1 in the plan view is larger than area a3 of third region A3 in the plan view (a1>a3). This is because area a1 of first region A1 is increased by the area of first gate electrode 19 provided in first region A1.

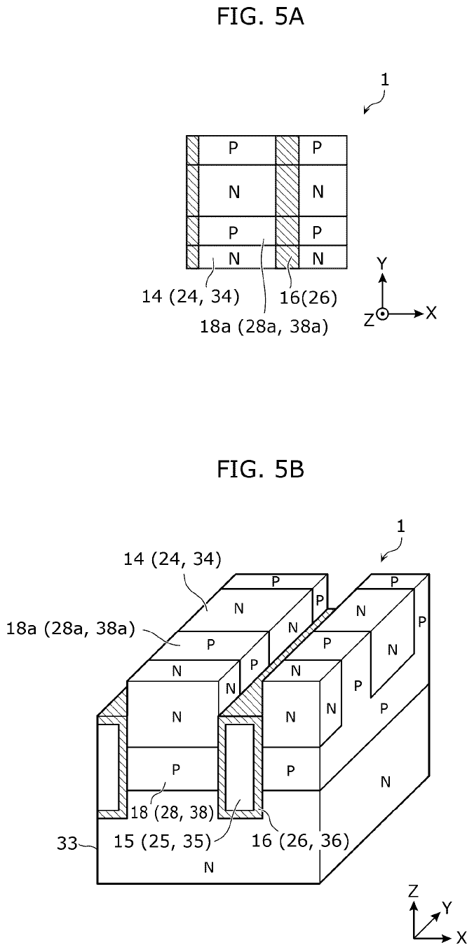

FIG. 5A and FIG. 5B are a planar schematic diagram and a perspective schematic diagram showing an approximate single unit configuration of each of transistor 10, transistor 20, and transistor 30 that is repeatedly formed in an X direction and a Y direction of semiconductor device 1 according to the embodiment, respectively. For the sake of clarity, FIG. 5A and FIG. 5B do not show semiconductor substrate 42, metal layer 41, passivation layer 45, first source electrode 11, second source electrode 21, third source electrode 31, and interlayer insulating layer 44.

It should be noted that the Y direction is a direction that is parallel to the surface of semiconductor layer 40 and in which first gate trench 17 extends. The X direction is a direction that is parallel to the surface of semiconductor layer 40 and orthogonal to the Y direction. A Z direction is a direction that is orthogonal to both the X direction and the Y direction and indicates a height direction of semiconductor device 1.

As shown in FIG. 5A and FIG. 5B, transistor 10 includes first connector 18a that electrically connects first body region 18 and first source electrode 11. First connector 18a is a region of first body region 18 in which first source region 14 is not provided, and is of the second conductivity type that is the same as first body region 18. First source region 14 and first connector 18a are alternately and periodically disposed in the Y direction. The same applies to transistor 20 and transistor 30.

In semiconductor device 1 according to the present disclosure, assuming that the first conductivity type is N-type and the second conductivity type is P-type, first source region 14, second source region 24, third source region 34, semiconductor substrate 42, and low-concentration impurity layer 43 are N-type semiconductors, and first body region 18, first connector 18a, second body region 28, second connector 28a, third body region 38, and third connector 38a are P-type semiconductors.

### 2. Operation of Semiconductor Device

In semiconductor device 1 according to the embodiment, it is assumed that a current enters through one of first source pad 111 of first region A1 or second source pad 121 of second region A2 as an inlet, flows through the common drain region and backside drain electrode 41, and exits through third source pad 131 as an outlet. In other words, driving that constitutes a conductive path from first source pad 111 to second source pad 121 or an other conductive path that is the reverse of the conductive path is not assumed in the embodiment.

In semiconductor device 1, a conductive path in which a current enters through first source pad 111 of first region A1 as an inlet and exits through third source pad 131 of third region A3 as an outlet is referred to as a first conductive path. A conductive path in which a current enters through second source pad 121 of second region A2 as an inlet and exits through third source pad 131 of third region A3 is referred to as a second conductive path.

In the first conductive path, a current flows as stated below. First, in semiconductor device 1, a high voltage and a low voltage are applied to first source electrode 11 and third source electrode 31, respectively, and a voltage that is sufficiently high and greater than or equal to a threshold value is applied (ON control) to first gate electrode 19 (first gate conductor 15) with respect to first source electrode 11. As a result, a conducting channel is formed in the vicinity of first gate insulating film 16 in first body region 18.

Moreover, the voltage applied to first gate electrode 19 is transmitted to third gate conductor 35 via first gate wiring 118, first diode 113, and third gate wiring 138. When this voltage is greater than or equal to the threshold value (ON control), a conducting channel is formed in the vicinity of third gate insulating film 36 in third body region 38. At this time, the current flows in a path from first source electrode 11—first source region 14—the conducting channel formed in first body region 18—low-concentration impurity layer 43—semiconductor substrate 42—metal layer 41—semiconductor substrate 42—low-concentration impurity layer 43—the conducting channel formed in third body region 38—third source region 34—third source electrode 31, and semiconductor device 1 becomes conductive.

The above path is the first conductive path. Semiconductor device 1 according to the embodiment has a structure in which ON control is automatically performed on transistor 30 when ON control is performed on transistor 10.

It should be noted that when the first conductive path is conducted, a PN junction in a contact surface between second body region 28 and low-concentration impurity layer 43 in transistor 20 is caused to serve as a body diode. This prevents conduction from first source pad 111 to second source pad 121. When the first conductive path is used in semiconductor device 1, a voltage greater than or equal to the threshold value need not be applied (OFF control) to second gate electrode 29 (second gate conductor 25) of transistor 20.

It should be noted that a certain voltage drop occurs in first diode 113. To conduct the first conductive path, it is necessary to adjust the voltage applied to first gate electrode 19 to be greater than a threshold value of transistor 30 by the voltage drop in first diode 113.

Although second gate wiring 128 is also connected to third gate wiring 138 via second diode 123, second diode 123 is provided in a direction from third gate wiring 138 to second gate wiring 128 as an electrically reverse direction. For this reason, the voltage applied to first gate electrode 19 is not transmitted to second gate wiring 128 (second gate conductor 25).

In addition, although second gate wiring 128 is also connected to third gate wiring 138 via second resistance element 124, a resistance value of second resistance element 124 is adjusted to a value that sufficiently decreases a voltage from third gate wiring 138. For this reason, the voltage applied to first gate electrode 19 is not transmitted as at least a value greater than or equal to a threshold value to second gate wiring 128 (second gate conductor 25).

In the second conductive path, a current flows as stated below. First, in semiconductor device 1, a high voltage and a low voltage are applied to second source electrode 21 and third source electrode 31, respectively, and a voltage that is sufficiently high and greater than or equal to a threshold value is applied (ON control) to second gate electrode 29 (second gate conductor 25) with respect to second source electrode 21. As a result, a conducting channel is formed in the vicinity of second gate insulating film 26 in second body region 28.

Moreover, the voltage applied to second gate electrode 29 is transmitted to third gate conductor 35 via second gate wiring 128, second diode 123, and third gate wiring 138. When this voltage is greater than or equal to the threshold value (ON control), a conducting channel is formed in the vicinity of third gate insulating film 36 in third body region 38. At this time, the current flows in a path from second source electrode 21—second source region 24—the conducting channel formed in second body region 28—low-concentration impurity layer 43—semiconductor substrate 42—metal layer 41—semiconductor substrate 42—low-concentration impurity layer 43—the conducting channel formed in third body region 38—third source region 34—third source electrode 31, and semiconductor device 1 becomes conductive.

The above path is the second conductive path. Semiconductor device 1 according to the embodiment has a structure in which ON control is automatically performed on transistor 30 when ON control is performed on transistor 20.

It should be noted that when the second conductive path is conducted, a PN junction in a contact surface between first body region 18 and low-concentration impurity layer 43 in transistor 10 is caused to serve as a body diode. This prevents conduction from second source pad 121 to first source pad 111. When the second conductive path is used in semiconductor device 1, a voltage greater than or equal to the threshold value need not be applied (OFF control) to first gate electrode 19 (first gate conductor 15) of transistor 10.

It should be noted that a certain voltage drop occurs in second diode 123. To conduct the second conductive path, it is necessary to adjust the voltage applied to second gate electrode 29 to be greater than a threshold value of transistor 30 by the voltage drop in second diode 123.

Although first gate wiring 118 is also connected to third gate wiring 138 via first diode 113, first diode 113 is provided in a direction from third gate wiring 138 to first gate wiring 118 as an electrically reverse direction. For this reason, the voltage applied to second gate electrode 29 is not transmitted to first gate wiring 118 (first gate conductor 15).

In addition, although first gate wiring 118 is also connected to third gate wiring 138 via first resistance element 114, a resistance value of first resistance element 114 is adjusted to a value that sufficiently decreases a voltage from third gate wiring 138. For this reason, the voltage applied to second gate electrode 29 is not transmitted as at least a value greater than or equal to a threshold value to first gate wiring 118 (first gate conductor 15).

As described so far, first diode 113 may have a structure including only one PN junction to reduce the occurrence of unnecessary drop of a voltage applied to first gate pad 119 as much as possible before the voltage is transmitted to third gate wiring 138. Additionally, first resistance element 114 is required to have a sufficiently high resistance value to cause the voltage applied to first gate pad 119 to drop to a voltage less than or equal to a threshold value before the voltage is transmitted to second gate wiring 128.

Similarly, second diode 123 may have a structure including only one PN junction to reduce the occurrence of unnecessary drop of a voltage applied to second gate pad 129 as much as possible before the voltage is transmitted to third gate wiring 138. Additionally, second resistance element 124 is required to have a sufficiently high resistance value to cause the voltage applied to second gate pad 129 to drop to a voltage less than or equal to a threshold value before the voltage is transmitted to first gate wiring 118.

It should be noted that although most of a current flowing inside semiconductor device 1 in a horizontal direction passes through metal layer 41 having a low resistivity both in the first conductive path and the second conductive path, a portion of the current may flow through semiconductor substrate 42.

### 3. Example of Using Semiconductor Device

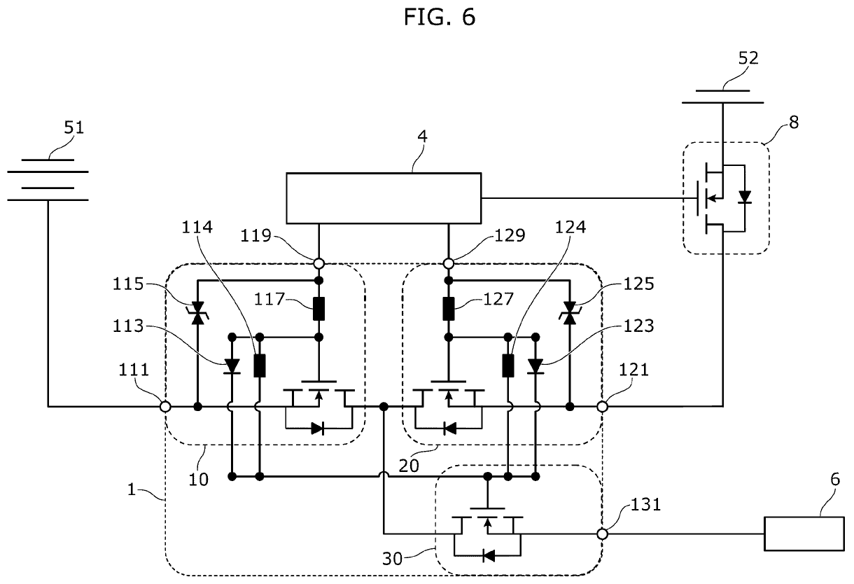

FIG. 6 is a circuit diagram showing a portion of a power supply system that passes a current from each of first power source 51 and second power source 52 that are removable to load 6 via semiconductor device 1 according to the embodiment. Here, an electric potential of first power source 51 is higher than an electric potential of second power source 52 with reference to an electric potential of load 6.

Semiconductor device 1 according to the embodiment is disposed to serve a function of integrating two paths of power supply from first power source 51 having the higher electric potential and power supply from second power source 52 having the lower electric potential into one path toward load 6 having a low electric potential in a downstream.

The maximum value of a current that flows due to the power supply from first power source 51 having the higher electric potential is denoted as I1 [A], and the maximum value of a current that flows due to the power supply from second power source 52 having the electric potential lower than the electric potential of first power source 51 is denoted as I2 [A]. It can be safely considered that I1 and I2 are each considered as a maximum current value in specification in a corresponding one of the first conductive path and the second conductive path described in a product data sheet of semiconductor device 1 according to the embodiment.

Since first power source 51 and second power source 52 have an electric potential relation, I1>I2 holds. A first power source 51 side through which relatively large current 11 flows is connected to first source pad 111 of transistor 10 having a large area in the plan view in semiconductor device 1. A second power source 52 side through which relatively small current I2 flows is connected to second source pad 121 of transistor 20 having a small area in the plan view in semiconductor device 1.

It should be noted that switching element 8 (e.g., a single vertical MOS transistor) is located between semiconductor device 1 and second power source 52. Switching element 8 and semiconductor device 1 are connected to control IC4. Control IC4 controls ON/OFF of switching element 8, transistor 10, and transistor 20 separately.

First, a state in which only first power source 51 is connected and second power source 52 is not connected (a state in which second power source 52 is not present in FIG. 6) is described. At this time, control IC4 performs ON control on transistor 10 and OFF control on transistor 20. Since the ON control is performed on transistor 10, the ON control is automatically performed on transistor 30 as well. Consequently, first power source 51 supplies power to load 6 via the first conductive path in semiconductor device 1.

The first conductive path is a conductive path inside semiconductor device 1 and, as described above, a conductive path in which a current enters through first source pad 111 of transistor 10 as an inlet and exits through third source pad 131 of transistor 30 as an outlet. When the first conductive path is conducted, OFF control is performed on transistor 20. Since the OFF control is performed on transistor 20, it is possible to cause a current that flows due to the power supply from first power source 51 not to flow toward the second power source 52 side.

Next, a state in which only second power source 52 is connected and first power source 51 is not connected (a state in which first power source 51 is not present in FIG. 6) is described. At this time, control IC4 performs ON control on transistor 20 and OFF control on transistor 10. Since the ON control is performed on transistor 20, the ON control is automatically performed on transistor 30 as well. Consequently, second power source 52 supplies power to load 6 via the second conductive path in semiconductor device 1.

The second conductive path is a conductive path inside semiconductor device 1 and, as described above, a conductive path in which a current enters through second source pad 121 of transistor 20 as an inlet and exits through third source pad 131 of transistor 30 as an outlet. When the second conductive path is conducted, OFF control is performed on transistor 10. Since the OFF control is performed on transistor 10, it is possible to cause a current that flows due to the power supply from second power source 52 not to flow toward the first power source 51 side.

When first power source 51 and second power source 52 are simultaneously connected (the state in FIG. 6), control IC4 first performs OFF control on switching element 8 and creates a state in which first power source 51 only supplies power. This is because first power source 51 has the higher electric potential and is superior in power supply. Additionally, ON control is also performed on transistor 30 by performing ON control on transistor 10 and OFF control on transistor 20, and first power source 51 supplies power to load 6 via the first conductive path.

### 4. Advantageous Effects of Semiconductor Device

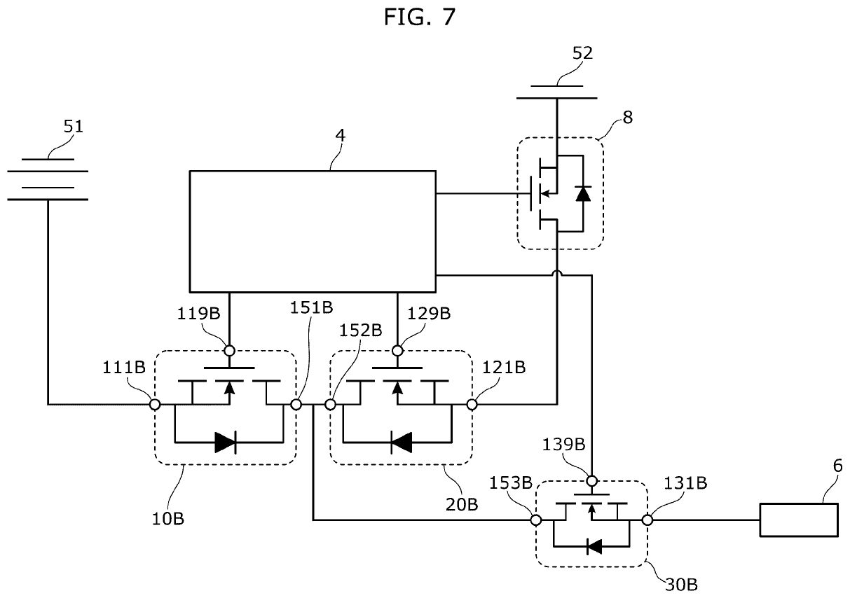

FIG. 7 shows a comparative example when semiconductor device 1 according to the embodiment is not used in the power supply system shown in FIG. 6. Hereinafter, advantageous effects achieved when semiconductor device 1 according to the embodiment is used are described by contrast with the comparative example.

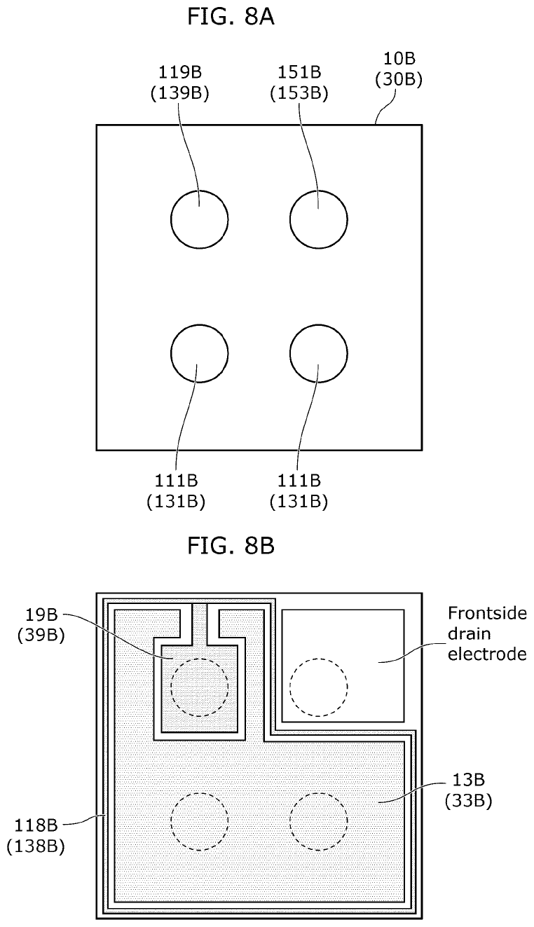

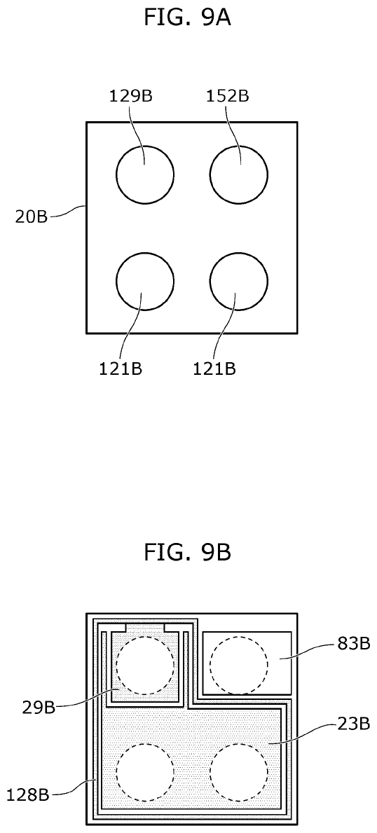

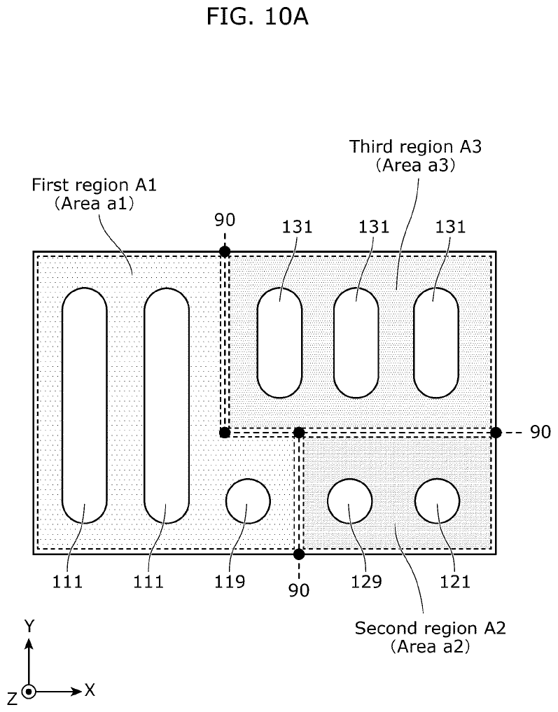

In the comparative example shown in FIG. 7, instead of semiconductor device 1 according to the embodiment, for example, vertical MOS transistor 10B (hereinafter referred to as transistor 10B) that includes a single configuration and of which examples of the structure are shown by planar schematic diagrams in FIG. 8A and FIG. 8B and vertical MOS transistor 20B (hereinafter referred to as transistor 20B) that includes a single configuration and of which examples of the structure are shown by planar schematic diagrams in FIG. 9A and FIG. 9B are used. In addition, vertical MOS transistor 30B (hereinafter referred to as transistor 30B) that includes a single configuration and of which the examples of the structure are shown by the planar schematic diagrams in FIG. 8A and FIG. 8B is connected immediately before load 6.

Constituent elements of transistor 10B, transistor 20B, and transistor 30B similar to those of semiconductor device 1 according to the embodiment are assigned the reference signs of the latter to which B is added.

Transistor 10B includes one drain pad 151B in addition to two source pads 111B and one gate pad 119B in the plan view. One drain pad 151B of transistor 10B is connected to a frontside drain electrode and serves as, for example, an outlet of a current flowing from two source pads 111B of transistor 10B.

Transistor 20B includes one drain pad 152B in addition to two source pads 121B and one gate pad 129B in the plan view. One drain pad 152B of transistor 20B is connected to a frontside drain electrode and serves as, for example, an outlet of a current flowing from two source pads 121B of transistor 20B.

Transistor 30B includes one drain pad 153B in addition to two source pads 131B and one gate pad 139B in the plan view. One drain pad 153B of transistor 30B is connected to a frontside drain electrode and serves as, for example, an outlet of a current flowing from two source pads 131B of transistor 30B.

As with the planar schematic diagram (FIG. 2B) showing semiconductor device 1 according to the embodiment, FIG. 8B and FIG. 9B each show a state immediately after portion 13B (23B, 33B) of a source electrode, gate electrode 19B (29B, 39B), gate wiring 118B (128B, 138B), and the frontside drain electrode to which drain pad 151B (152B, 153B) is connected are provided on the front face side of semiconductor layer 40. For the sake of clarity, pads that cannot be seen at this moment are indicated by the dashed lines in FIG. 8B and FIG. 9B.

The area of portion 13B of a source electrode of transistor 10B in the plan view is equal to the area of portion 13 of first source electrode 11 of transistor 10 included in semiconductor device 1 according to the embodiment in the plan view. Additionally, the area of portion 33B of a source electrode of transistor 30B in the plan view is equal to the area of portion 33 of third source electrode 31 of transistor 30 included in semiconductor device 1 according to the embodiment in the plan view. Accordingly, it can be safely considered that a conductive resistance of a path in which a current flows from first power source 51 to load 6 via transistor 10B and transistor 30B in FIG. 7 is equal to a conductive resistance of the first conductive path of semiconductor device 1 according to the embodiment in FIG. 6.

Moreover, the area of portion 23B of a source electrode of transistor 20B in the plan view is equal to the area of portion 23 of second source electrode 21 of transistor 20 included in semiconductor device 1 according to the embodiment in the plan view. Accordingly, it can be safely considered that a conductive resistance of a path in which a current flows from second power source 52 to load 6 via transistor 20B and transistor 30B in FIG. 7 is equal to a conductive resistance of the second conductive path of semiconductor device 1 according to the embodiment in FIG. 6.

In the power supply system shown in FIG. 7, when only first power source 51 is connected (second power source 52 is not present in FIG. 7), control IC4 performs OFF control on transistor 20B and causes a current that flows due to the power supply from first power source 51 not to flow toward the second power source 52 side. Additionally, ON control is performed on transistor 10B by applying a voltage greater than or equal to a threshold value to gate pad 119B of transistor 10B, and ON control is performed on transistor 30B by applying a voltage greater than or equal to the threshold value to gate pad 139B of transistor 30B as well.

Accordingly, the current that flows due to the power supply from first power source 51 enters through source pad 111B of transistor 10B and exits through drain pad 151B, and subsequently enters through drain pad 153B of transistor 30B and exits through source pad 131B. As shown in FIG. 8A and FIG. 8B, the reason why the area of transistor 10B (the area of portion 13B of the source electrode) in the plan view is relatively large is because the current that flows due to the power supply from first power source 51 is relatively large.

In the power supply system shown in FIG. 7, when only second power source 52 is connected (first power source 51 is not present in FIG. 7), control IC4 performs the OFF control on transistor 10B and causes a current that flows due to the power supply from second power source 52 not to flow toward the first power source 51 side. Additionally, the ON control is performed on transistor 20B by applying a voltage greater than or equal to the threshold value to gate pad 129B of transistor 20B, and the ON control is performed on transistor 30B by applying a voltage greater than or equal to the threshold value to gate pad 139B of transistor 30B as well.

Accordingly, the current that flows due to the power supply from second power source 52 enters through source pad 121B of transistor 20B and exits through drain pad 152B, and subsequently enters through drain pad 153B of transistor 30B and exits through source pad 131B. As shown in FIG. 9A and FIG. 9B, the reason why the area of transistor 20B (the area of portion 23B of the source electrode) in the plan view is relatively small is because the current that flows due to the power supply from second power source 52 is relatively small.

As stated above, transistor 10B and transistor 30B in the power supply system according to the comparative example shown in FIG. 7 serve the same functions as transistor 10 and transistor 30 in the power supply system shown in FIG. 6, which are included in semiconductor device 1 according to the embodiment. Likewise, transistor 20B and transistor 30B in the power supply system according to the comparative example shown in FIG. 7 serve the same functions as transistor 20 and transistor 30 in the power supply system shown in FIG. 6, which are included in semiconductor device 1 according to the embodiment.

However, in a circuit substrate including the power supply system according to the comparative example shown in FIG. 7, it is necessary to ensure the area of each of transistor 10B, transistor 20B, and transistor 30B and a certain arrangement margin to be provided between transistor 10B, transistor 20B, and transistor 30B. Additionally, since each of transistor 10B, transistor 20B, and transistor 30B includes a drain pad (151B, 152B, 153B) in the plan view, transistor 10B, transistor 20B, and transistor 30B each include a structure that requires a certain area.

On the other hand, in a circuit substrate including the power supply system shown in FIG. 6, it is possible to integrate transistor 10B, transistor 20B, and transistor 30B according to the comparative example into one transistor by using semiconductor device 1 according to the embodiment. Accordingly, it is possible to eliminate the need for the certain arrangement margin to be provided between transistor 10B, transistor 20B, and transistor 30B that is required in the circuit substrate including the power supply system according to the comparative example.

Additionally, semiconductor device 1 according to the embodiment makes it possible to remove the respective drain pads (151B, 152B, 153B) included in transistor 10B, transistor 20B, and transistor 30B in the comparative example. What is more, since third transistor 30 includes no gate pads, semiconductor device 1 according to the embodiment also makes it possible to eliminate the need for gate pad 139B provided in transistor 30B (FIG. 8B) in the comparative example shown in FIG. 7.

As state above, the use of semiconductor device 1 according to the embodiment makes it possible to significantly reduce the area necessary for the circuit substrate. The circuit substrate including the power supply system shown in FIG. 6 makes it possible not only to reduce the substrate itself but also to provide other components in a resultant surplus portion, compared to the comparative example.

Accordingly, semiconductor device 1 according to the embodiment is a facedown mountable, chip-size-package type semiconductor device and includes: semiconductor layer 40 that includes semiconductor substrate 42 on a back face side and is divided into first region A1, second region A2, and third region A3 that do not overlap each other and are not dispersedly disposed in a plan view of semiconductor device 1; first vertical metal-oxide-semiconductor (MOS) transistor 10 an entirety of which is provided in first region A1 of semiconductor layer 40; second vertical MOS transistor 20 an entirety of which is provided in second region A2 of semiconductor layer 40; third vertical MOS transistor 30 an entirety of which is provided in third region A3 of semiconductor layer 40; and metal layer 41 that is provided in contact with the back face side of semiconductor layer 40. Semiconductor substrate 42 is a common drain region of first vertical MOS transistor 10, second vertical MOS transistor 20, and third vertical MOS transistor 30. In the plan view, first source pad 111 and first gate pad 119 of first vertical MOS transistor 10 and first gate wiring 118 connected to first gate pad 119 are provided at positions within first region A1. In the plan view, second source pad 121 and second gate pad 129 of second vertical MOS transistor 20 and second gate wiring 128 connected to second gate pad 129 are provided at positions within second region A2. In the plan view, third source pad 131 of third vertical MOS transistor 30 and third gate wiring 138 are provided at positions within third region A3. First gate wiring 118 and third gate wiring 138 are electrically connected in series via first diode 113 in a direction from first gate wiring 118 to third gate wiring 138 as a forward direction. Second gate wiring 128 and third gate wiring 138 are electrically connected in series via second diode 123 in a direction from second gate wiring 128 to third gate wiring 138 as a forward direction.

Since semiconductor device 1 according to the embodiment includes first diode 113, semiconductor device 1 includes a structure in which, when ON control is performed on transistor 10, the ON control is automatically performed on transistor 30 as well, and the first conductive path becomes conductive. At this time, since second diode 123 is provided in an electrically reverse direction when viewed from third gate wiring 138, the ON control is not performed on transistor 20.

Likewise, since semiconductor device 1 according to the embodiment includes second diode 123, semiconductor device 1 includes a structure in which, when ON control is performed on transistor 20, the ON control is automatically performed on transistor 30 as well, and the second conductive path becomes conductive. At this time, since first diode 113 is provided in an electrically reverse direction when viewed from third gate wiring 138, the ON control is not performed on transistor 10.

First diode 113 includes one end connected to first gate wiring 118 and an other end connected to third gate wiring 138. Similarly, second diode 123 includes one end connected to second gate wiring 128 and an other end connected to third gate wiring 138.

Accordingly, in semiconductor device 1 according to the embodiment, the one end of first diode 113 is located in first region A1 and the other end of first diode 113 is located in third region A3 in the plan view, and the one end of second diode 123 is located in second region A2 and the other end of second diode 123 is located in third region A3 in the plan view.

The provision of first diode 113 and second diode 123 in the above manner also produces an effect of avoiding an unnecessary reduction of the conductive area of the first conductive path or the second conductive path.

As shown in FIG. 2B, first diode 113 is typically disposed to extend across boundary line 90 (the dashed line from P1 to P2) between first region A1 and third region A3 in the plan view. When first EQR 116 and third EQR 136 are disposed in first region A1 and third region A3, respectively, although a portion in which first EQR 116 and third EQR 136 are shared becomes boundary line 90 between first region A1 and third region A3 in the plan view, it is necessary to partially divide the shared EQR to dispose first diode 113.

Accordingly, in semiconductor device 1 according to the embodiment, first EQR 116 may be provided on at least a portion of an outer periphery of first region A1 in the plan view, third EQR 136 may be provided on at least a portion of an outer periphery of third region A3 in the plan view, first EQR 116 and third EQR 136 may be shared in a portion in which first region A1 and third region A3 are opposite to each other, and first diode 113 may be disposed in a portion in which first EQR 116 and third EQR 136 are not shared. In other words, in the plan view, first diode 113 may be disposed in a portion at which the shared EQR that becomes boundary line 90 between first region A1 and third region A3 is broken off.

In the power supply system shown in FIG. 6, no voltage may be applied to both first gate pad 119 and second gate pad 129. At this time, an electric potential may remain in first gate wiring 118 and third gate wiring 138 or second gate wiring 128 and third gate wiring 138, depending on the previous use state of semiconductor device 1.

When first gate wiring 118 and third gate wiring 138 are connected via first resistance element 114, it is advantageous because a path that transfers the remaining electric potential of first gate wiring 118 and third gate wiring 138 to first gate pad 119 is provided although a resistance value of first resistance element 114 is high. Similarly, when second gate wiring 128 and third gate wiring 138 are connected via second resistance element 124, it is advantageous because a path that transfers the remaining electric potential of second gate wiring 128 and third gate wiring 138 to second gate pad 129 is provided although a resistance value of second resistance element 124 is high.

Accordingly, in semiconductor device 1 according to the embodiment, first gate wiring 118 and third gate wiring 138 may be connected in series via first resistance element 114, first diode 113 and first resistance element 114 may be connected in parallel between first gate wiring 118 and third gate wiring 138, second gate wiring 128 and third gate wiring 138 may be connected in series via second resistance element 124, and second diode 123 and second resistance element 124 may be connected in parallel between second gate wiring 128 and third gate wiring 138.

First resistance element 114 includes one end connected to first gate wiring 118 and an other end connected to third gate wiring 138. Likewise, second resistance element 124 includes one end connected to second gate wiring 128 and an other end connected to third gate wiring 138.

Accordingly, in semiconductor device 1 according to the embodiment, the one end of first resistance element 114 may be located in first region A1 and the other end of first resistance element 114 may be located in third region A3 in the plan view, and the one end of second resistance element 124 may be located in second region A2 and the other end of second resistance element 124 may be located in third region A3 in the plan view.

The provision of first resistance element 114 and second resistance element 124 in the above manner produces the effect of avoiding an unnecessary reduction of the conductive area of the first conductive path or the second conductive path.

In semiconductor device 1 according to the embodiment, the first conductive path uses first source pad 111 in first region A1 as an inlet and third source pad 131 in third region A3 as an outlet. For this reason, when first region A1 and third region A3 are adjacent to each other in the plan view, it is advantageous because it is possible to reduce a conductive resistance by shortening the first conductive path. Similarly, the second conductive path uses second source pad 121 in second region A2 as an inlet and third source pad 131 in third region A3 as an outlet. For this reason, when second region A2 and third region A3 are adjacent to each other in the plan view, it is advantageous because it is possible to reduce a conductive resistance by shortening the second conductive path.

Accordingly, in the plan view, first region A1 and second region A2 may be disposed with third region A3 interposed therebetween, and third region A3 may be adjacent to first region A1 and second region A2.

In semiconductor device 1 according to the embodiment, the emphasis is placed on reducing a conductive resistance of the first conductive path. For this reason, as shown in FIG. 2A or FIG. 2B, in the plan view, an opposite length (the length of the dashed line from P1 to P2) of first region A1 and third region A3 may be greater than an opposite length (the length of the dashed line from P3 to P4 via P5) of second region A2 and third region A3. When an arrangement in the plan view of semiconductor device 1 is made as above, it is possible to expand a portion of the first conductive path that has the highest current density (extend an opposite length). Accordingly, it is possible to reduce the conductive resistance.

In semiconductor device 1 according to the embodiment, the areas of the inlet and the outlet in the plan view may be substantially equal in the first conductive path that conducts a relatively large current. This is because when one of the inlet or the outlet is relatively small, the one of the inlet or the outlet becomes a bottleneck and the conductive resistance increases.

Accordingly, in semiconductor device 1 according to the embodiment, a first source electrode of first vertical MOS transistor 10 may be provided at a position within first region A1 in the plan view, a third source electrode of third vertical MOS transistor 30 may be provided at a position within third region A3 in the plan view, and an area of the first source electrode may be substantially equal to an area of the third source electrode in the plan view. The terms “first source electrode” and “third source electrode” refer to portion 13 of first source electrode 11 and portion 33 of third source electrode 31 that are in direct contact with semiconductor layer 40, respectively.

Moreover, in semiconductor device 1 according to the embodiment, since neither a gate pad nor a gate electrode is present in third region A3 in the plan view, even when portion 13 of first source electrode 11 and portion 33 of third source electrode 31 have the same area in the plan view, it is possible to decrease area a3 of third region A3 compared to area a1 of first region A1.

It should be noted that since the second conductive path has a small current in specification, it is possible to decrease a conductive area in consideration of the small current. At this time, that the area of the outlet (portion 33 of third source electrode 31) in the plan view is larger than the area of the inlet (portion 23 of second source electrode 21) does not pose a problem.

Accordingly, in semiconductor device 1 according to the embodiment, in the plan view, area a1 of first region A1 may be larger than area a3 of third region A3, and area a3 of third region A3 may be larger than area a2 of second region A2. It should be noted that a difference between area a1 of first region A1 in the plan view and area a3 of third region A3 in the plan view is approximately one first gate pad 119.

FIG. 10A and FIG. 10B each are a planar schematic diagram showing a variation of the structure of semiconductor device 1 according to the embodiment. As with FIG. 2B, FIG. 10B shows a state immediately after portion 13 of first source electrode 11, first gate electrode 19, first gate wiring 118, portion 23 of second source electrode 21, second gate electrode 29, second gate wiring 128, third portion 33 of third source electrode 31, and third gate wiring 138 are provided on the front face side of semiconductor layer 40. Pads that cannot be seen at this moment are indicated by dashed lines.

Compared to FIG. 2A and FIG. 2B, in the variation shown in FIG. 10A and FIG. 10B, third region A3 is not interposed between first region A1 and second region A2, and there is a portion in which first region A1 and second region A2 are adjacent to each other. Additionally, in the plan view, first gate pad 119 is disposed at a position in first region A1 close to third region A3.

That first gate pad 119 is disposed at the position in first region A1 close to third region A3 means that no portion of first source pad 111 is interposed between first gate pad 119 and third region A3 closest to first gate pad 119 in first region A1.

Such an arrangement makes it possible to decrease a connection distance between first gate pad 119 and third gate wiring 138. Accordingly, since it is possible to quickly transmit a voltage applied to first gate pad 119 to third gate wiring 138, it is possible to improve a response speed of semiconductor device 1. This effect applies to an arrangement of second gate pad 129 and third region A3 in the plan view.

Accordingly, first gate pad 119 may be disposed at the position close to third region A3 in the plan view, and second gate pad 129 may be disposed at the position close to third region A3.

In the examples shown in both FIG. 2B and FIG. 10B, when at least one of first Zener diode 115 or second Zener diode 125 is provided in semiconductor device 1, at least one of first diode 113 or second diode 123 may be simultaneously provided. The simultaneous provision makes it possible to manufacture semiconductor device 1 easily.

Both at least one of first Zener diode 115 or second Zener diode 125 and at least one of first diode 113 or second diode 123 are diodes in the first place. By controlling formation positions and the number of PN junctions or directions of electric PN junctions, the at least one of first Zener diode 115 or second Zener diode 125 and the at least one of first diode 113 or second diode 123 are allowed to serve respective functions. As shown in FIG. 2B, the at least one of first Zener diode 115 or second Zener diode 125 and the at least one of first diode 113 or second diode 123 merely differ in in-plane installation positions in the plan view of semiconductor device 1. For this reason, the simultaneous provision is made possible by changing injection positions of impurities in a plane accordingly.

At this time, a comparison of respective regions indicating the same conductivity type included in first diode 113 and first Zener diode 115 in the plan view shows that concentrations of impurities of the same conductivity type in the respective regions are equal to each other. That the concentrations of the impurities are equal means that concentration profiles of the impurities when a region and another region are compared in a depth direction substantially match each other.

Accordingly, in the plan view, (portion 13 of) first source electrode 11 and first gate electrode 19 of first vertical MOS transistor 10 may be provided at positions within first region A1; in the plan view, first Zener diode 115 may be provided between (portion 13 of) first source electrode 11 and first gate electrode 19; and impurities of the same conductivity type in regions of the same conductivity type included in first diode 113 and in first Zener diode 115 may have the same concentration.

Likewise, when at least one of first gate resistance element 117 or second gate resistance element 127 is provided in semiconductor device 1, at least one of first resistance element 114 or second resistance element 124 may be simultaneously provided. The simultaneous provision makes it possible to manufacture semiconductor device 1 easily.

Accordingly, in the plan view, first gate electrode 19 of first vertical MOS transistor 10 may be provided in first region A1; in the plan view, first gate resistance element 117 may be provided between first gate electrode 19 and first gate wiring 118; and impurities of the same conductivity type in regions of the same conductivity type included in first resistance element 114 and first gate resistance element 117 may have the same concentration.

### 5. Additional Discussion

The following refers back to the example shown in FIG. 6 in which semiconductor device 1 according to the embodiment is used. In a transistor in the ON state, since a total gate width generally increases when the area of the transistor in a plan view is large, a conductive resistance decreases. In other words, the area of the transistor in the plan view and the conductive resistance are in an inverse proportion relation on the whole.

In semiconductor device 1, area a1 of transistor 10 constituting the first conductive path in the plan view is larger than area a2 of transistor 20 constituting the second conductive path in the plan view. For this reason, the first conductive path has a lower conductive resistance and is a path suitable for passing a relatively large current.

Conductive resistance R1 [Ω] of the first conductive path may be determined in consideration of maximum value I1 [A] of a current that flows due to power supply from first power source 51. Similarly, conductive resistance R2 [Ω] of the second conductive path may be determined in consideration of maximum value I2 [A] of a current that flows due to power supply from second power source 52. Accordingly, in semiconductor device 1 according to the embodiment, the respective areas of transistor 10 and transistor 20 may be determined to achieve a conductive resistance suitable for each of the first conductive path and the second conducive path.

However, when the area of each of the transistors in the plan view determined as described above is excessively small, ESD tolerance may deteriorate. This is because when the area of the transistor in the plan view is small, an excessive voltage applied to the gate electrode or a surge current is not sufficiently dispersed in a cell (a gate conductor) of the transistor.

When an electrostatic discharge (ESD) tolerance rated value is hereinafter denoted by ESDt [V], in semiconductor device 1 according to the embodiment, transistor 20 having the smallest area is required to achieve tolerance greater than or equal to ESDt. When the power supply system as shown in FIG. 6 is used, ESDt required in semiconductor device 1 is typically approximately 1000 [V] to 2000 [V].

In order to achieve a desired ESDt, disposing at least one of second Zener diode 125 or second gate resistance element 127 in transistor 20 is described. However, since disposing second Zener diode 125 results in providing a path that connects second gate pad 129 (second gate electrode 29) and second source pad 121 (portion 23 of second source electrode 21) as shown by a portion of transistor 20 in FIG. 6, such disposing produces a side effect of causing a gate-source leakage current.

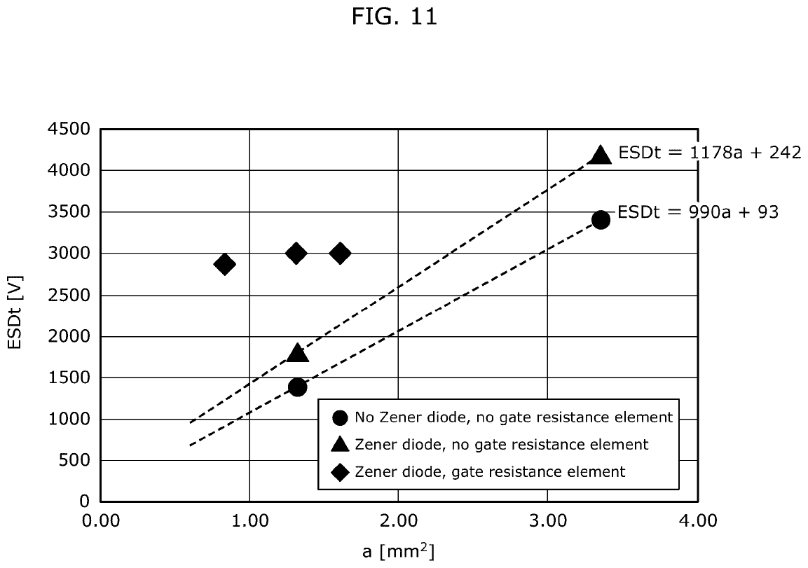

FIG. 11 shows a relation between area a [mm²] of a transistor in the plan view and maximum voltage value ESDt [V] that the inventors were able to confirm did not damage the transistor when applied to a gate pad, the relation being verified by the inventors through experiments. The horizontal axis indicates a, and the vertical axis indicates ESDt. It should be noted that area a of the transistor in the plan view refers to area a1 of first region A1 in the plan view or area a2 of second region A2 in the plan view in the example of semiconductor device 1 according to the embodiment. To put it another way, area a includes the area of a region that does not contribute to conduction.

Data plotted by circular markers are obtained from a transistor in which neither a Zener diode nor a gate resistance element is disposed. Data plotted by triangular markers are obtained from a transistor in which only a Zener diode is disposed and a gate resistance element is not disposed. Data plotted by rhomboid markers are obtained from a transistor in which both a Zener diode and a gate resistance element are disposed.

It is clear from FIG. 11 that when the gate resistance element is not disposed, ESDt tends to increase with an increase in area a of the transistor. It is also clear that even when area a of the transistor is not increased, disposing the Zener diode causes ESDt to increase. When the gate resistance element is disposed in addition to the Zener diode, it is possible to achieve substantially constant ESDt regardless of the area of the transistor.

When it is desired to set an ESD rated value of semiconductor device 1 according to the embodiment to, for example, 2000 [V], ideally, 2000 [V] may be rated for transistor 20 having the smallest area in the plan view. According to FIG. 11, when area a2 of transistor 20 in the plan view is less than approximately 2.0 [mm²], second Zener diode 125 or second gate resistance element 127 may be disposed. On the other hand, when it is desired to avoid an increase in gate-source leakage current caused by disposing second Zener diode 125, it is better not to dispose second Zener diode 125. When a necessary ESD rated value is 2000 [V], area a2 of transistor 20 in the plan view may be at least approximately 2.0 [mm²].

Consequently, according to the data plotted by the circular markers in FIG. 11, when an electrostatic discharge tolerance rated value described in a product data sheet of semiconductor device 1 is denoted by ESDt [V] and the area of second region A2 in the plan view is denoted by a2 [mm²], a2> (ESDt-93)/990 may be satisfied.

Moreover, at this time, portion 23 of second source electrode 21 and second gate electrode 29 of second vertical MOS transistor 20 may be provided at positions within second region A2 in the plan view, a path that electrically connects portion 23 of second source electrode 21 and second gate electrode 29 need not be present, and second gate electrode 29 and second gate wiring 128 may be connected not via a resistance element.

Such a structure makes it possible to achieve a desired ESD rated value (ESDt [V]) in semiconductor device 1 while avoiding the increase in gate-source leakage current in transistor 20.

At this time, in transistor 10 having a much larger area in the plan view in semiconductor device 1, sufficient ESDt is supposed to be already achieved. Accordingly, portion 13 of first source electrode 11 and first gate electrode 19 of first vertical MOS transistor 10 may be provided at positions within first region A1 in the plan view, a path that electrically connects portion 13 of first source electrode 11 and first gate electrode 19 need not be present, and first gate electrode 19 and first gate wiring 118 may be connected not via a resistance element.

Such a structure makes it possible to avoid an unnecessary increase in gate-source leakage current in transistor 10.

It should be noted that, with regard to area a2 of second region A2 in the plan view, even when a2< (ESDt-93)/990 holds, it may be possible to achieve a desired ESD rated value by disposing at least one of second Zener diode 125 or second gate resistance element 127.

Accordingly, portion 13 of first source electrode 11 and first gate electrode 19 of first vertical MOS transistor 10 may be provided at positions within first region A1 in the plan view, a path that electrically connects portion 13 of first source electrode 11 and first gate electrode 19 need not be present, first gate electrode 19 and first gate wiring 118 may be connected not via a resistance element, portion 23 of second source electrode 21 and second gate electrode 29 of second vertical MOS transistor 20 may be provided at positions within second region A2 in the plan view, portion 23 of second source electrode 21 and second gate electrode 29 are connected via second Zener diode 125, and second gate electrode 29 and second gate wiring 128 may be connected in series via second gate resistance element 127.

Such a structure makes it possible to achieve a desired ESD rated value (ESDt [V]) of semiconductor device 1 while avoiding an unnecessary increase in gate-source leakage current in transistor 10.

Although the semiconductor device according to one aspect of the present disclosure is described based on the embodiment and the variation, the present disclosure is not limited to the embodiment. Forms obtained by various modifications to the embodiment that can be conceived by a person skilled in the art as well as forms realized by combining constituent elements in different embodiments and variations are included in the scope of one or more aspects of the present disclosure, as long as they do not depart from the essence of the present disclosure.

Although only the exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The semiconductor device including the vertical MOS transistor according to the present disclosure is widely applicable as a device that controls a conducting state of a current path.

1. A semiconductor device that is a facedown mountable, chip-size-package type semiconductor device, the semiconductor device comprising:
a semiconductor layer that includes a semiconductor substrate on a back face side and is divided into a first region, a second region, and a third region that do not overlap each other and are not dispersedly disposed in a plan view of the semiconductor device;
a first vertical metal-oxide semiconductor (MOS) transistor an entirety of which is provided in the first region of the semiconductor layer;
a second vertical MOS transistor an entirety of which is provided in the second region of the semiconductor layer;
a third vertical MOS transistor an entirety of which is provided in the third region of the semiconductor layer; and
a metal layer that is provided in contact with the back face side of the semiconductor layer,
wherein the semiconductor substrate is a common drain region of the first vertical MOS transistor, the second vertical MOS transistor, and the third vertical MOS transistor,
in the plan view, a first source pad and a first gate pad of the first vertical MOS transistor and first gate wiring connected to the first gate pad are provided at positions within the first region,
in the plan view, a second source pad and a second gate pad of the second vertical MOS transistor and second gate wiring connected to the second gate pad are provided at positions within the second region,
in the plan view, a third source pad of the third vertical MOS transistor and third gate wiring are provided at positions within the third region,
the first gate wiring and the third gate wiring are electrically connected in series via a first diode in a direction from the first gate wiring to the third gate wiring as a forward direction, and
the second gate wiring and the third gate wiring are electrically connected in series via a second diode in a direction from the second gate wiring to the third gate wiring as a forward direction.

2. The semiconductor device according to claim 1,
wherein the first diode includes one end located in the first region and an other end located in the third region, and
the second diode includes one end located in the second region and an other end located in the third region.

3. The semiconductor device according to claim 1,
wherein the first gate wiring and the third gate wiring are further connected in series via a first resistance element,
the first diode and the first resistance element are connected in parallel between the first gate wiring and the third gate wiring,
the second gate wiring and the third gate wiring are further connected in series via a second resistance element, and
the second diode and the second resistance element are connected in parallel between the second gate wiring and the third gate wiring.

4. The semiconductor device according to claim 3,
wherein the first resistance element includes one end located in the first region and an other end located in the third region, and
the second resistance element includes one end located in the second region and an other end located in the third region.

5. The semiconductor device according to claim 1,
wherein in the plan view, the first region and the third region are adjacent to each other, and the second region and the third region are adjacent to each other.

6. The semiconductor device according to claim 1,
wherein in the plan view, an area of the first region is larger than an area of the third region, and
the area of the third region is larger than an area of the second region.

7. The semiconductor device according to claim 6,
wherein in the plan view, a first source electrode of the first vertical MOS transistor is provided at a position within the first region,
in the plan view, a third source electrode of the third vertical MOS transistor is provided at a position within the third region, and
in the plan view, an area of the first source electrode is substantially equal to an area of the third source electrode.

8. The semiconductor device according to claim 1,
wherein in the plan view, a first equipotential ring (EQR) is provided on at least a portion of an outer periphery of the first region,
in the plan view, a third EQR is provided on at least a portion of an outer periphery of the third region,
in the plan view, the first EQR and the third EQR are shared in a portion in which the first region and the third region are opposite to each other, and
in the plan view, the first diode is disposed in a portion in which the first EQR and the third EQR are not shared.

9. The semiconductor device according to claim 1,
wherein in the plan view, the first gate pad is disposed at a position close to the third region, and
in the plan view, the second gate pad is disposed at a position close to the third region.

10. The semiconductor device according to claim 1,
wherein in the plan view, a first source electrode and a first gate electrode of the first vertical MOS transistor are provided at positions within the first region,
in the plan view, a first Zener diode is provided between the first source electrode and the first gate electrode, and
impurities of a same conductivity type in regions of the same conductivity type included in the first diode and the first Zener diode have a same concentration.

11. The semiconductor device according to claim 3,
wherein in the plan view, a first source electrode and a first gate electrode of the first vertical MOS transistor are provided at positions within the first region,
in the plan view, a first gate resistance element is provided between the first gate electrode and the first gate wiring, and
impurities of a same conductivity type in regions of the same conductivity type included in the first resistance element and the first gate resistance element have a same concentration.

12. The semiconductor device according to claim 1,
wherein in the plan view, a gate electrode connected to the third gate wiring and a gate pad are not provided at positions within the third region.

13. The semiconductor device according to claim 6,
wherein when an electrostatic discharge tolerance rated value described in a product data sheet of the semiconductor device is denoted by ESDt [V] and the area of the second region in the plan view is denoted by a2 [mm²], a2> (ESDt-93)/990 is satisfied.

14. The semiconductor device according to claim 13,
wherein in the plan view, a second source electrode and a second gate electrode of the second vertical MOS transistor are provided at positions within the second region,
a path that electrically connects the second source electrode and the second gate electrode is not present, and
the second gate electrode and the second gate wiring are connected not via a resistance element.

15. The semiconductor device according to claim 14,
wherein in the plan view, a first source electrode and a first gate electrode of the first vertical MOS transistor are provided at positions within the first region,
a path that electrically connects the first source electrode and the first gate electrode is not present, and
the first gate electrode and the first gate wiring are connected not via a resistance element.

16. The semiconductor device according to claim 6,
wherein in the plan view, a first source electrode and a first gate electrode of the first vertical MOS transistor are provided at positions within the first region,
a path that electrically connects the first source electrode and the first gate electrode is not present,
the first gate electrode and the first gate wiring are connected not via a resistance element,
in the plan view, a second source electrode and a second gate electrode of the second vertical MOS transistor are provided at positions within the second region,
the second source electrode and the second gate electrode are connected via a second Zener diode, and
the second gate electrode and the second gate wiring are connected in series via a second gate resistance element.
